(19) United States
(12) Patent Application Publication
(10) Pub. No.: US 2023/0048600 A1
(43) Pub. Date: Feb. 16, 2023

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventors: Tzung-Han LEE, Hefei City (CN); Chih-Cheng LIU, Hefei City (CN)

(73) Assignee: CHANGXIN MEMORY TECHNOLOGIES, INC., Hefei City (CN)

(21) Appl. No.: 17/651,574

(22) Filed: Feb. 17, 2022

Related U.S. Application Data
(63) Continuation of application No. PCT/CN2021/116873, filed on Sep. 7, 2021.

(30) Foreign Application Priority Data
Aug. 16, 2021 (CN) 202110935828.6

(51) Int. Cl. H01L 21/66

(52) U.S. Cl. CPC H01L 22/32

(57) ABSTRACT

A semiconductor structure includes the following: a semiconductor substrate; a first metal layer, located on a surface of the semiconductor substrate; a second metal layer, located above a surface of the first metal layer; an insulating layer, located between the first metal layer and the second metal layer, and configured to isolate the first metal layer and the second metal layer; a test via, penetrating through the insulating layer and connecting the first metal layer with the second metal layer through a conductive material in the test via; and at least a pair of dummy vias, penetrating through the insulating layer and connected to any one of the first metal layer and the second metal layer.

### CROSS-REFERENCE TO RELATED APPLICATIONS

This is a continuation of International Application No. PCT/CN2021/116873 filed on Sep. 7, 2021, which claims priority to Chinese Patent Application No. 202110935828.6 filed on Aug. 16, 2021. The disclosures of these applications are hereby incorporated by reference in their entirety.

### BACKGROUND

Semiconductor devices such as a memory and a chip are usually realized by adopting a multi-layer structure on a semiconductor substrate. An electrical connection within each layer on a surface of the semiconductor substrate is realized by metal wires, and the metal wires of different layers are connected through vias. The resistance value of the vias is an important parameter affecting the connection performance. Therefore, a test key is usually formed in a manufacturing process to test the resistance of the via.

However, the test key is located at a periphery of a device and there are no other structures around it, which is easy to cause deformation of the via, so that a test result is difficult to reflect the actual resistance value of the via inside the device.

### SUMMARY

The embodiment of the disclosure relates, but is not limited, to a semiconductor structure and a method for manufacturing a semiconductor structure.

The embodiment of the disclosure provides a semiconductor structure and a method for manufacturing a semiconductor structure.

In a first aspect, the semiconductor structure provided in the embodiment of the disclosure includes a semiconductor substrate, a first metal layer, a second metal layer, an insulating layer, a test via and at least a pair of dummy vias.

The first metal layer is located on a surface of the semiconductor substrate.

The second metal layer is located above a surface of the first metal layer.

The insulating layer is located between the first metal layer and the second metal layer, and configured to isolate the first metal layer and the second metal layer.

The test via penetrates through the insulating layer and connects the first metal layer with the second metal layer through a conductive material in the test via.

The at least a pair of dummy vias penetrates through the insulating layer and is connected to any one of the first metal layer and the second metal layer.

In a second aspect, a method for manufacturing a semiconductor structure provided in the embodiments of the disclosure includes the following operations.

A first metal layer is formed on a surface of a semiconductor substrate.

An insulating layer is formed on the first metal layer.

A test via and at least a pair of dummy vias penetrating through the insulating layer are formed.

The test via and the dummy vias are filled with a conductive material.

A second metal layer is formed on the insulating layer, the test via and the dummy vias. The test via is connected to the first metal layer and the second metal layer, and the dummy vias are connected to any one of the first metal layer and the second metal layer.

### BRIEF DESCRIPTION OF THE DRAWINGS

One or more embodiments are exemplified by pictures in corresponding accompanying drawings, unless otherwise stated, the figures in the accompanying drawings do not constitute a proportional limitation.

FIG. 1 is a schematic diagram one of a semiconductor structure provided in an embodiment of the disclosure.

FIG. 2 is a schematic diagram of a semiconductor structure with one test via.

FIG. 3 is a schematic diagram two of a semiconductor structure provided in an embodiment of the disclosure.

FIG. 4 is a schematic diagram of a first metal layer in a semiconductor structure provided in an embodiment of the disclosure.

FIG. 5 is a schematic diagram of positions of a first metal layer, a test via and dummy vias in a semiconductor structure provided in an embodiment of the disclosure.

FIG. 6 is a flowchart of a method for manufacturing a semiconductor structure provided in an embodiment of the disclosure.

FIG. 7 is a schematic diagram three of a semiconductor structure provided in an embodiment of the disclosure.

FIG. 8 is a schematic diagram of one test via formed in an embodiment.

FIG. 9 is a schematic diagram of a semiconductor structure formed in an embodiment.

FIG. 10 is a schematic diagram four of a semiconductor structure provided in an embodiment of the disclosure.

FIG. 11 is a sectional diagram of positions of a test via and dummy vias in a semiconductor structure provided in an embodiment of the disclosure.

### DETAILED DESCRIPTION

In order to facilitate the understanding of the disclosure, the disclosure will be described in more detail below with reference to related accompanying drawings. Preferred embodiments of the disclosure are shown in the accompanying drawings. However, the disclosure may be implemented in many different forms and are not limited to the embodiments described herein. On the contrary, an objective of providing these embodiments is to make the disclosed content of the disclosure more thorough and comprehensive.

Unless otherwise defined, all technical and scientific terms used herein shall have the same meanings as commonly understood by those skilled in the art to which the disclosure belongs. The terms used herein in the specification of the disclosure are only used to describe specific embodiments, but are not intended to limit the disclosure. The term “and/or” used herein includes any and all combinations of one or more of the associated listed items.

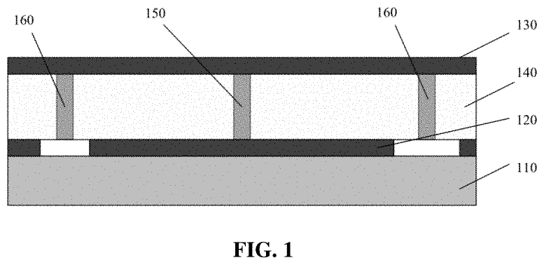

The embodiment of the disclosure provides a semiconductor structure. As illustrated in FIG. 1, the semiconductor structure 100 includes a semiconductor substrate 110, a first metal layer 120, a second metal layer 130, an insulating layer 140, a test via 150 and at least a pair of dummy vias 160.

The first metal layer 120 is located on a surface of the semiconductor substrate 110.

The second metal layer 130 is located above a surface of the first metal layer 120.

The insulating layer 140 is located between the first metal layer 120 and the second metal layer 130, and configured to isolate the first metal layer 120 and the second metal layer 130.

The test via 150 penetrates through the insulating layer 140 and connects the first metal layer 120 with the second metal layer 130 through a conductive material in the test via 150.

The at least a pair of dummy vias 160 penetrates through the insulating layer 140 and is connected to any one of the first metal layer 120 and the second metal layer 130.

In the embodiment of the disclosure, the semiconductor structure may be a test structure, or referred to as a test key, located at a periphery of semiconductor devices and configured to perform testing. The semiconductor structure may be formed synchronously with the semiconductor devices in the process of manufacturing various semiconductor devices (such as a memory or a chip) by using a wafer. Since the semiconductor structure is separated from the semiconductor device, the performance of the semiconductor device is not affected.

The semiconductor structure can be configured to perform testing in the manufacturing process of the semiconductor devices, so as to realize the process monitoring of the semiconductor devices. When manufacturing of the semiconductor devices is completed, an area where the semiconductor structure is located may be cut off, only the semiconductor devices are retained and encapsulated respectively. The above semiconductor structure may also be retained and packaged with the semiconductor device together, so as to facilitate the test of a product.

The first metal layer and the second metal layer are metal layers formed synchronously with different metal layers in the semiconductor device. Both the first metal layer and the second metal layer may have patterns formed by etching, such as linear or mesh patterns. The first metal layer and the second metal layer are isolated from each other through the insulating layer. The insulating layer may be made of an insulating material such as silicon oxide or silicon nitride.

The first metal layer and the second metal layer may be connected with each other through vias, which penetrate through the insulating layer. The test via is connected to the first metal layer and the second metal layer, so that the first metal layer and the second metal layer can be electrically connected through the test via. The dummy vias only connect with any one of the first metal layer and the second metal layer, so as to play the role of supporting and balancing stress.

In the embodiment of the disclosure, the dummy vias has a structure similar to the test via and penetrate the insulating layer. The dummy vias may also contain a conductive material such as a metal, but they do not have the function of connecting the first metal layer and the second metal layer. That is, the dummy vias are only connected to the first metal layer or only connected to the second metal layer.

The dummy vias may be configured to support the whole semiconductor structure. For example, the position distribution of the dummy vias and the test via may be centrosymmetric or axisymmetric, so as to make the semiconductor structure more stable. Or, the dummy vias may be distributed around the test via, play the role of supporting the test via and reducing the test inaccuracy caused by the deformation of the test via. Moreover, the dummy vias may improve the distribution of exposure energy at the area where the vias locate, and improve the morphology of a process window and the vias. Meanwhile, a single via is easy to deform in subsequent processes. With disposing of the at least a pair of dummy vias, the deformation of the via in the subsequent process may be avoided.

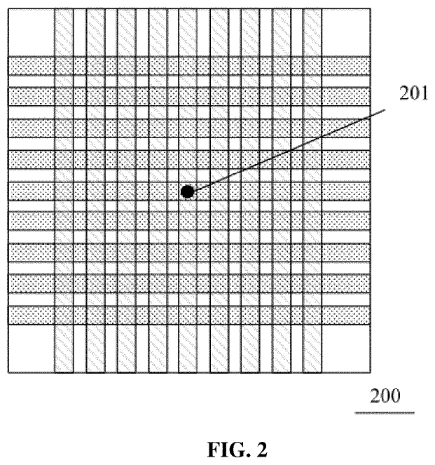

Compared with a structure in which only a test via 201 is disposed in the semiconductor structure 200 illustrated in FIG. 2, the semiconductor structure in the embodiment of the disclosure has a more stable structure and is not easy to deform in the manufacturing process. Therefore, the accuracy and efficiency of testing with the semiconductor structure are improved.

In some embodiments, the first metal layer includes a plurality of bottom metal wires distributed in parallel along a first direction.

The second metal layer includes a plurality of top metal wires distributed in parallel along a second direction. The second direction is perpendicular to the first direction.

In the embodiment of the disclosure, the first metal layer may be linear metal wires and may include a plurality of metal wires distributed side by side. Since the first metal layer is a metal layer close to a surface of the substrate, these metal wires may be called bottom metal wires. Here, the plurality of bottom metal wires may be distributed in parallel along the first direction, and the first direction may be any direction parallel to the surface of the substrate, as long as it is easily realized in the actual manufacturing process.

In the embodiment of the disclosure, the second metal layer may be a plurality of parallel distributed metal wires similar to the structure of the first metal layer. Compared with the first metal layer, the second metal layer is away from the surface of the substrate, so that it may be called top metal wires. The plurality of top metal wires are distributed in parallel along the second direction. The second direction may be perpendicular to the first direction, which may make the structure more stable.

In some embodiments, the test via is located at an overlapping position of a bottom metal wire and a top metal wire.

The metal wires of the first metal layer and the second metal layer are perpendicular to each other. Therefore, each bottom metal wire of the first metal layer and each top metal wire of the second metal layer have overlapping positions respectively. These overlapping positions are located in the same straight line in the direction perpendicular to the surface of the substrate. Therefore, the above test via may be formed at these overlapping positions, so as to realize the connection between the first metal layer and the second metal layer.

In some embodiments, the bottom metal wire connected with the test via has two test ends, and the top metal wire connected with the test via has two test ends.

The test ends are configured to test the resistance of the test via by a Kelvin four-wire detection method.

Because the test via is connected to a top metal wire and a bottom metal wire perpendicular to each other, the two metal wires have two test ends respectively, and a total of four test ends can be provided.

The Kelvin four-wire detection method is also called four-terminal detection, or four-point probe method. The method may eliminate impedance of wiring and contact resistance by separating electrodes of current and voltage, so as to realize accurate resistance test. In the embodiment of the disclosure, the metal wires connected to at least four vias may be connected to different detection ends respectively, so as to realize the four-wire detection. Compared with a single-point test method, the detection accuracy can be improved.

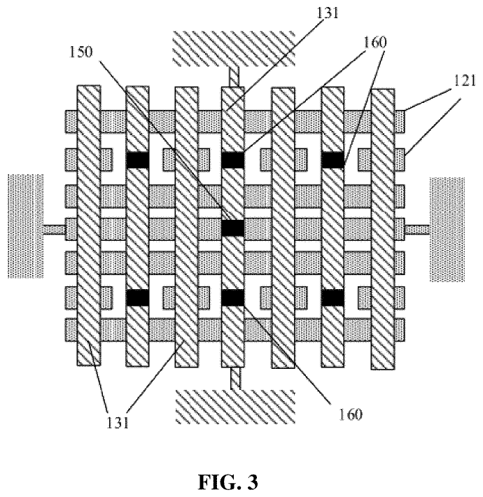

In some embodiments, as illustrated in FIG. 3, the at least a pair of dummy vias 160 includes a pair of dummy vias 160 connected to the same top metal wire 131 as the test via 150.

When the top metal wire is formed, if the top metal wire is deformed, it is easy to cause the deformation of the test via, thus affecting a test result. In the embodiment of the disclosure, the dummy vias are disposed at positions of the top metal wire that is connected to the test via, so as to play a supporting role, reduce probability of deformation of the top metal wire, and then reduce the test inaccuracy caused by the deformation of the test via.

In some embodiments, as illustrated in FIG. 3, the at least a pair of dummy vias 160 includes at least two pairs of dummy vias 160 connected to a top metal wire 131 different from that the test via 150 connects. The at least a pair of dummy vias 160 includes at least two pairs of dummy vias 160 connected to bottom metal wires 121 different from that the test via 150 connects.

In the embodiment of the disclosure, a plurality of pairs of dummy vias may be disposed around the test via, not only including the dummy vias connected to the same top metal wire as the test via connects, but also including a plurality of pairs of dummy vias connected to different top metal wires and bottom metal wires from those connected with the test via. Thus, the plurality of dummy vias can make the semiconductor structure more stable and reduce the influence of deformation. Moreover, the dummy vias can improve the distribution of exposure energy at the area where the vias are distributed, and improve the morphology of a process window and the vias.

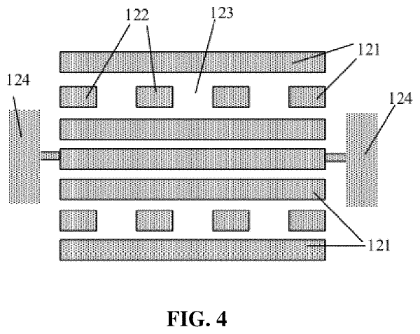

In some embodiments, as illustrated in FIG. 4, at least two of the plurality of bottom metal wires 121 respectively include at least two spaced metal wire segments 122, and spacing areas 123 are between two adjacent metal wire segments 122.

By considering that each dummy via is only connected to either a top metal wire or a bottom metal wire, some of the bottom metal wires may be set as a plurality of spaced metal wire segments, and there is a spacing area between every two adjacent metal wire segments.

These bottom metal wires do not have a connection function and only have a function of simulating the structure in semiconductor device. Therefore, these bottom metal wires do not need to be connected to the test via, or do not need to have external test ends, either.

It is to be noted that, the bottom metal wire connected to the test via does not have such structure, but is an intact metal wire, and has an external test end 124 as illustrated in FIG. 4. A bottom metal wire with spacing areas may be located adjacent to an intact bottom metal wire or at another position spaced apart from the intact bottom metal wire.

In some embodiments, projections of the at least three top metal wires on the semiconductor substrate are partly located in projections of the spacing areas on the semiconductor substrate.

Thus, at least three top metal wires and these bottom metal wires cannot be connected through the vias at the overlapping positions. That is, the bottom metal wire composed of a plurality of metal wire segments at least has three spacing areas, so it is convenient to set a plurality of dummy vias.

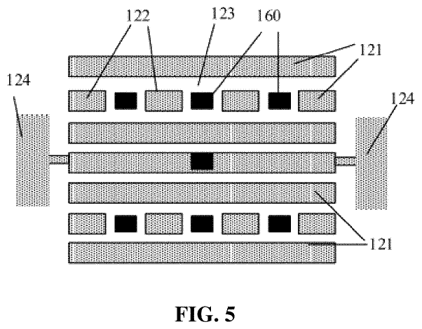

In some embodiments, as illustrated in FIG. 5, the top ends of the dummy vias 160 are connected with the top metal wires (not illustrated in the figure), and the bottom ends of the dummy via 160 is connected with the spacing areas 123.

Thus, a part of the overlapping positions of the top metal wires and the bottom metal wires are in the spacing areas of the bottom metal wires. One end of one dummy via is connected to a top metal wire, and the other end may be connected to the above said spacing area, so that the first metal layer and the second metal layer will not be connected.

In some embodiments, the distribution pattern of the test via and the at least a pair of dummy vias are axisymmetric or centrosymmetric.

The dummy vias and the test via together form a symmetrical structure, which can make the semiconductor structure have a balanced and stable structure, and can be used for repeated testing without being damaged easily.

In some embodiments, the dummy vias form a first axisymmetric distribution with the center line of the semiconductor structure as the axis, and the distances from dummy vias to the center of the semiconductor structure in the first axisymmetric distribution may be different. The test via may be located on the central axis. If there are a plurality of test vias, they may also be symmetrically distributed relative to the center line. The distances between each dummy vias and the test via may be the same or different.

In some embodiments, the test via and the dummy vias form a first centrosymmetric distribution centered on the center of the semiconductor structure, and the distances from the dummy vias in first centrosymmetric distribution to the center of the semiconductor structure are the same. The center of the semiconductor structure is the symmetry center. If there is only a test via, it may be located at the symmetry center. If there are a plurality of test vias, they may be centrosymmetric with the symmetry center.

In some embodiments, the dummy vias are filled with a conductive material.

In the embodiment of the disclosure, the dummy vias and the test via may be manufactured synchronously with the same process flow. Thus, the dummy vias may have structures completely consistent with the test via, that is, structures filled with the conductive material. Since the dummy vias are located in the spacing areas of the bottom metal wires, the bottom metal wires will not be conductively connected. Therefore, on one hand, the manufacturing process can be saved. On the other hand, the distribution of exposure energy at the area where the vias are distributed can be improved, and the morphology of the process window and the vias can be improved.

In other embodiments, the dummy vias may also be filled with insulating materials, such as organic materials and oxides, thus reducing the electrical interference between the vias.

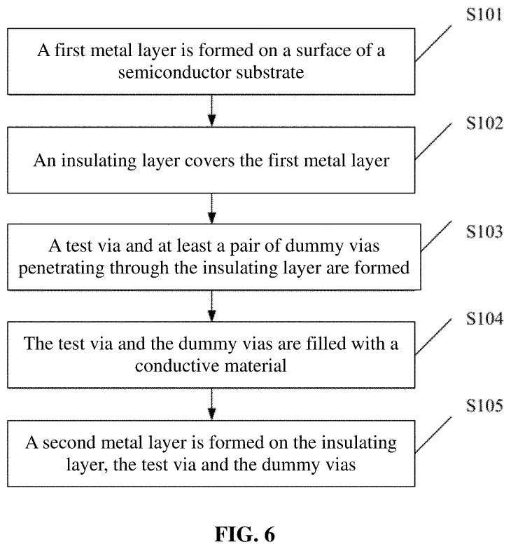

The embodiment of the disclosure also provides a method for manufacturing a semiconductor structure. As illustrated in FIG. 6, the method may include the following steps.

At S101, a first metal layer is formed on a surface of a semiconductor substrate.

At S102, an insulating layer covers the first metal layer.

At S103, a test via and at least a pair of dummy vias penetrating through the insulating layer are formed.

At S104, the test via and the dummy vias are filled with a conductive material.

At S105, a second metal layer is formed on the insulating layer, the test via and the dummy vias. The test via is connected to the first metal layer and the second metal layer, and the dummy vias are connected to any one of the first metal layer and the second metal layer.

Since the semiconductor structure may be a test structure located around the semiconductor device and configured to perform testing, the manufacturing process of the semiconductor structure is executed synchronously in a process of manufacturing a semiconductor device product. The first metal layer, the second metal layer and the insulating layer are formed synchronously with each corresponding layer in the semiconductor device.

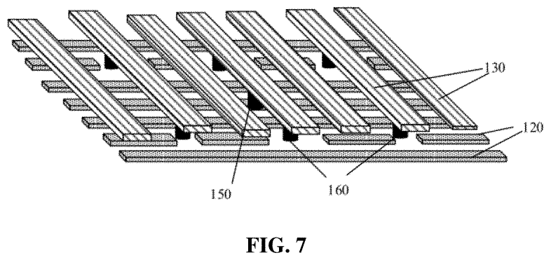

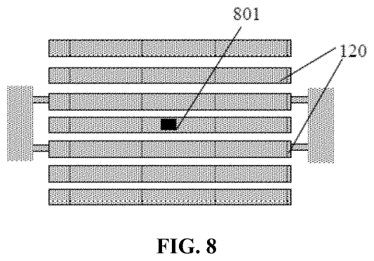

The test via and the dummy vias are also formed synchronously with a process of forming vias in the semiconductor device. As illustrated in FIG. 7, after the insulating layer (not illustrated in the figure) is formed on the first metal layer 120, the test via 150 and the dummy vias 160 are synchronously formed at a plurality of target positions, and then subsequent related processes of the second metal layer 130 and the like are executed. Compared with the mode of only forming one via 801 in the first metal layer 120 as illustrated in FIG. 8, the whole structure can be more stable. Moreover, the distribution of exposure energy at the area where the vias are distributed can be improved, and the morphology of the process window and the vias can be improved. Meanwhile, a single via is easy to deform in a subsequent process. With disposing of at least a pair of dummy vias, the deformation of the via in the subsequent process can be avoided.

In some embodiments, the first metal layer is formed on the surface of the semiconductor substrate, including the following operation.

A plurality of bottom metal wires distributed in parallel along the first direction are formed on the surface of the semiconductor substrate.

The second metal layer is formed on the insulating layer, the test via and the dummy vias, including the following operation.

A plurality of top metal wires distributed in parallel along the second direction are formed on the insulating layer, the test via and the dummy via. The second direction is perpendicular to the first direction.

Here, a metal layer may be formed on the surface of the semiconductor substrate, and then a plurality of metal wires may be formed by patterning and etching.

After the first metal layer is formed, an insulating material may be deposited on it to form an insulating layer.

In some embodiments, at least two of the plurality of bottom metal wires respectively include at least two spaced metal wire segments, and spacing areas are between two adjacent metal wire segments.

After the bottom metal wires are formed, partial areas of some metal wires may be removed by etching to form the spacing areas, so that these bottom metal wires form a plurality of spaced metal wire segments.

In some embodiments, top ends of the dummy vias are connected with the top metal wires, and bottom ends of the dummy vias are connected with the spacing areas.

Thus, the dummy vias may be formed synchronously with the test via, and the top metal wire may be connected with the dummy vias. When the dummy vias are connected to the first metal layer, because the positions are located in the spacing areas, they will not be connected with the bottom metal wire, so that they do not have test function and will not produce electrical interference to the test via, but they can play a role of supporting and stabilizing the semiconductor structure.

In some embodiments, projections of the at least three top metal wires on the semiconductor substrate are partly located in projections of the spacing areas on the semiconductor substrate.

In this way, there is no metal overlapping position between these top metal wires and the bottom metal wires with spacing areas, and the dummy vias are connected with the spacing areas, and are not connected to the bottom metal wires.

The embodiment of the disclosure also provides following examples.

For an back end of line (BEOL) process of metal-oxide-semiconductor (MOS) field-effect transistor devices and the like, each layer of metal is connected through vias. An traditional isolation test-key (ISO Test-key) generally tests the resistance of a single via.

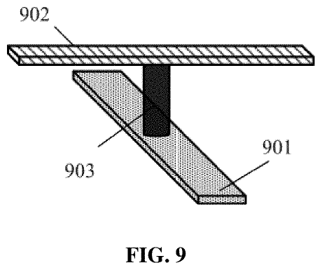

As illustrated in FIG. 9, the test structure of a via includes a bottom metal wire 901, a top metal wire 902 and a test via 903 located at the overlapping position of the two metal wires and connected with the two metal wires. The via of this structure is easily affected by a surrounding isolation layer, resulting in the instability of a photoetching process. There is no other graphic structure around the single test via, which causes the deformation of the test via easily in the subsequent processes of flattening the metal layer and the like, and therefore, testing cannot be performed. Moreover, the resistance value of a single test via has a high probability of error, which may not accurately reflect the resistance value of the actual vias in the device.

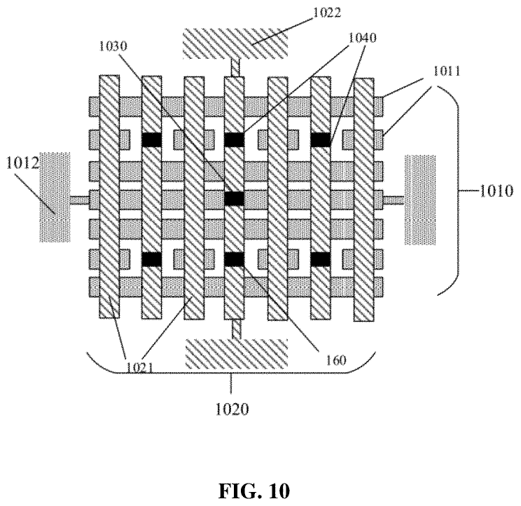

In the embodiment of the disclosure, as illustrated in FIG. 10, the first metal layer 1010 includes a plurality of bottom metal wires 1011, and the second metal layer 1020 includes a plurality of top metal wires 1021. At an overlapping position where a bottom metal wire intersects with a top metal wire, a test via 1030 is set, and the test via 1030 is connected to the bottom metal wire 1011 and the top metal wire 1021. Moreover, an insulating layer (not illustrated in the figure) is provided between the first metal layer 1010 and the second metal layer 1020.

The bottom metal wire 1011 and the top metal wire 1021 respectively connected with the test via 1030 are connected with test pads 1012 and 1022 respectively, so that the resistance of the test via 1030 can be tested by the Kelvin test method by using the test pads 1012 and 1022.

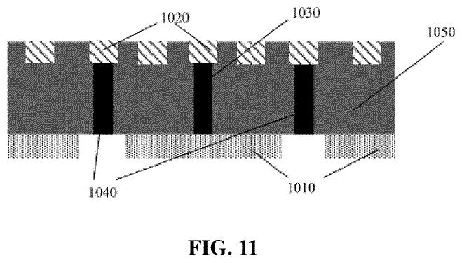

Moreover, in order to stabilize the whole semiconductor structure, dummy vias 1040 may also be disposed. As illustrated in FIG. 11, the dummy vias 1040 are connected with the second metal layer 1020, penetrate through the insulating layer 1050 between the first metal layer 1010 and the second metal layer 1020, but are not connected with the first metal layer 1010. In the embodiment of the disclosure, the bottom metal wires of the first metal layer may have a plurality of disconnected distributed metal wire segments, and the disconnected parts have spacing areas. Thus, when the dummy vias are connected to the positions of the first metal layer, they contact the spacing areas without contacting the metal wires, so that the first metal layer will not be conductively connected.

The dummy vias 1040 and other vias may be configured to form a stable and symmetrical structure to reduce the possibility of deformation of the test via. Therefore, the dummy vias 1040 do not need to have conductivity, and the dummy vias 1040 may be filled with an insulating material, as illustrated in FIG. 11. Of course, to simplify the manufacturing process, the dummy vias may be formed simultaneously with the test via, and the dummy vias are filled with a metal material. However, since the dummy vias are not connected with the bottom metal wires of the first metal layer, the first metal layer and the second metal layer will not be conductively connected.

It should be understood that “one embodiment” or “an embodiment” mentioned throughout the specification means that specified features, structures, or characteristics related to the embodiment are included in at least one embodiment of the disclosure. Therefore, “in one embodiment” or “in an embodiment” appearing throughout the specification does not necessarily refer to a same embodiment. In addition, these specified features, structures, or characteristics may be combined in one or more embodiments in any appropriate manner. It should be understood that, in the embodiments of this disclosure, sequence numbers of the foregoing processes do not mean execution sequences. The execution sequences of the processes should be determined according to functions and internal logic of the processes, and should not be construed as any limitation on the implementation processes of the embodiments of the disclosure. The sequence numbers of the embodiments of the above-mentioned disclosure are merely for the description, and do not represent the advantages and disadvantages of the embodiments.

It is to be noted that, herein, terms “include” and “contain” or any other variants thereof are intended to cover nonexclusive inclusions, so that, a process, a method, or an apparatus including a series of elements not only includes those elements but also includes other elements which are not clearly listed or further includes intrinsic elements of the process, the method or the apparatus. Under the condition of no more limitations, an element defined by a statement “including a/an” does not exclude existence of additional same elements in the process, the method, or the apparatus.

In several embodiments provided by the disclosure, it is to be understood that the disclosed device and method may be implemented in other manners. The device embodiment described above is only schematic, and for example, division of the units is only logic function division, and other division manners may be adopted during practical implementation. For example, a plurality of units or components may be combined or integrated into another system, or some characteristics may be neglected or not executed. In addition, coupling or direct coupling or communication connection between each displayed or discussed component may be indirect coupling or communication connection, implemented through some interfaces, of the device or the units, and may be electrical and mechanical or adopt other forms.

The above-mentioned units described as separate parts may be or may not be physically separate, and the parts shown as units may be or may not be physical elements, which may be located in one place or distributed to a plurality of network elements. Part or all of the units may be selected to achieve the objectives of the solutions of the embodiments according to practical requirements.

In addition, each function unit in each embodiment of the disclosure may be integrated into a processing unit, each unit may also serve as an independent unit and two or more than two units may also be integrated into a unit. The integrated unit may be implemented in a hardware form and may also be implemented in form of hardware and software function unit.

The foregoing descriptions are merely implementation manners of the disclosure, but are not intended to limit the scope of protection of the disclosure. Any variation or replacement readily figured out by a person skilled in the art within the technical scope disclosed in the disclosure shall fall within the scope of protection of the disclosure. Therefore, the scope of protection of the disclosure shall be subject to the scope of protection of the claims.

### INDUSTRIAL APPLICABILITY

The embodiment of the disclosure provides a semiconductor structure and a method for manufacturing a semiconductor structure. According to the technical solution provided in the embodiment of the disclosure, a semiconductor structure provided in the embodiment of the disclosure adopts at least a pair of dummy vias disposed at different positions around a test via, which on one hand, play a role of supporting, and the possibility of deformation of the test via in the manufacturing process can be reduced; and on the other hand, improve the distribution of exposure energy at the area where the vias are distributed and improve the morphology of a process window and the vias. Meanwhile, a single via is easy to deform in the subsequent process, however, with the at least a pair of dummy vias, the deformation of the via in subsequent processes can be avoided.

What is claimed is:

1. A semiconductor structure, comprising:
a semiconductor substrate;
a first metal layer, located on a surface of the semiconductor substrate;
a second metal layer, located above a surface of the first metal layer;
an insulating layer, located between the first metal layer and the second metal layer, and configured to isolate the first metal layer and the second metal layer;
a test via, penetrating through the insulating layer and connecting the first metal layer with the second metal layer through a conductive material in the test via; and
at least a pair of dummy vias, penetrating through the insulating layer and connected to any one of the first metal layer or the second metal layer.

2. The semiconductor structure according to claim 1, wherein the first metal layer comprises a plurality of bottom metal wires distributed in parallel along a first direction; and
the second metal layer comprises a plurality of top metal wires distributed in parallel along a second direction, wherein the second direction is perpendicular to the first direction.

3. The semiconductor structure according to claim 2, wherein the test via is located at an overlapping position of a bottom metal wire and a top metal wire.

4. The semiconductor structure according to claim 3, wherein the bottom metal wire connected to the test via has two test ends, and the top metal wire connected to the test via has two test ends; and
the test ends are configured to test a resistance of the test via by a Kelvin four-wire detection method.

5. The semiconductor structure according to claim 3, wherein the at least a pair of dummy vias comprises a pair of dummy vias connected to the same top metal wire as the test via.

6. The semiconductor structure according to claim 2, wherein the at least a pair of dummy vias comprises at least two pairs of dummy vias connected to top metal wires different from the top metal wire that the test via is connected to, or the at least a pair of dummy vias comprises at least two pairs of dummy vias connected to bottom metal wires different from the bottom metal wire that the test via is connected to.

7. The semiconductor structure according to claim 6, wherein at least two of the plurality of bottom metal wires respectively comprise at least two spaced metal wire segments, and spacing areas are between two adjacent metal wire segments.

8. The semiconductor structure according to claim 7, wherein the at least two of the plurality of bottom metal wires respectively comprise at least four spaced metal wire segments, and projections of at least three top metal wires on the semiconductor substrate are partly located in projections of spacing areas on the semiconductor substrate.

9. The semiconductor structure according to claim 7, wherein top ends of the dummy vias are connected with the top metal wires, the bottom ends of the dummy vias are connected with spacing areas.

10. The semiconductor structure according to claim 1, wherein a distribution pattern of the test via and the at least a pair of dummy vias is axisymmetric or centrosymmetric.

11. The semiconductor structure according to claim 1, wherein the dummy via s are filled with conductive material.

12. A method for manufacturing a semiconductor structure, comprising:
forming a first metal layer on a surface of a semiconductor substrate;
forming an insulating layer on the first metal layer;
forming a test via and at least a pair of dummy vias penetrating through the insulating layer;
filling the test via and the dummy vias with conductive material; and
forming a second metal layer on the insulating layer, the test via and the dummy vias, wherein the test via is connected to the first metal layer and the second metal layer, and the dummy vias are connected to any one of the first metal layer and the second metal layer.

13. The method according to claim 12, wherein forming the first metal layer on the surface of the semiconductor substrate comprises:
forming a plurality of bottom metal wires distributed in parallel along a first direction on the surface of the semiconductor substrate; and
forming the second metal layer on the insulating layer, the test via and the dummy via comprises:
forming a plurality of top metal wires distributed in parallel along a second direction on the insulating layer, the test via and the dummy vias, wherein the second direction is perpendicular to the first direction.

14. The method according to claim 13, wherein at least two of the plurality of bottom metal wires respectively comprise at least two spaced metal wire segments, and spacing areas are between two adjacent metal wire segments.

15. The method according to claim 14, wherein top ends of the dummy vias are connected to the top metal wires, and bottom ends of the dummy vias are connected to spacing areas.

16. The method according to claim 15, wherein the at least two of the plurality of bottom metal wires respectively comprise at least four spaced metal wire segments, and projections of the at least three top metal wires on the semiconductor substrate are partly located in projections of spacing areas on the semiconductor substrate.
